(19) United States
(12) Patent Application Publication
(10) Pub. No.: US 2004/0018650 A1
(43) Pub. Date: Jan. 29, 2004

(54) Substrate processing apparatus

(75) Inventors: Ryota Sasajima, Tokyo (JP); Hironobu Miya, Tokyo (JP); Naoto Nakamura, Tokyo (JP)

Correspondence Address: BACON & THOMAS, PLLC, 625 SLATERS LANE, FOURTH FLOOR, ALEXANDRIA, VA, 22314

(73) Assignee: Hitachi Kokusai Electric Inc., Tokyo (JP)

(21) Appl. No.: 10/457,518

(22) Filed: Jun. 10, 2003

(30) Foreign Application Priority Data
Jun. 11, 2002 (JP) 2002-169787

(51) Int. Cl. H01L 21/66

(52) U.S. Cl. 438/14; 436/149; 374/142; 134/113; 422/82.12

(57) ABSTRACT

Pollution caused by chemical pollutants can be estimated automatically. A chemical pollutants detecting unit 60 installed in a duct 33 includes a supporting shaft 61, which is inserted into a sidewall 11a of a housing, for supporting the chemical pollutants detecting unit 60, a quartz crystal microbalance 62 for detecting organic matters in a clean air 53 passing through the duct 33, an oscillating circuit 63 for oscillating the quartz crystal microbalance 62, an oscillation frequency detecting block 64, a chemical pollutants calculating block 65, a controller 66, an output unit 67, a heater 68 for heating the quartz crystal microbalance 62, and a thermo-hygrometer 70. A chemical filter is examined automatically whether an ability of removing the chemical pollutants thereby is degraded or not. If the ability is found to have been degraded, efficiency in an IC manufacturing method can be prevented from being degraded by issuing an alarming signal beforehand.

### FIELD OF THE INVENTION

The present invention relates to a substrate processing apparatus (or a wafer processing apparatus); and, more particularly, to a scheme for preventing pollution caused by organic matters, the scheme being used, e.g., in a batch-type vertical apparatus for performing CVD (chemical vapor deposition) or diffusion process, that forms a CVD layer such as an insulating layer, a metal layer, and the like, or diffuses impurities on a semiconductor wafer (hereinafter, wafer), with a plurality of ICs (integrated circuits), which include a plurality of semiconductor devices, being imbedded therein.

### BACKGROUND OF THE INVENTION

A batch-type vertical apparatus for performing CVD or diffusion process (hereinafter, CVD apparatus) is prevalently used in an IC manufacturing process for forming a CVD layer such as an insulating layer, a metal layer, and the like, or diffusing impurities on a wafer. Considering a conventional CVD apparatus, a clean unit for spouting clean air is installed in a housing to restrain particles (dust) having a side effect on an efficiency of IC manufacturing method.

Recently, the fact that chemical pollutants in a form of gas with high reactivity, such as acid gas, alkali gas, and organic gas contaminate wafers is elucidated. For example, “ACTUAL CONDITIONS ABOUT CONTAMINATION IN ULSI (ultra large scale integration) MANUFACTURE AND ABOUT MANUFACTURING SITE AND TOPIC FOR FUTURE DISCUSSION” published by REALIZE co., clearly indicates that the number of electric badness in the IC is reduced by preventing organic matters, such as DOP (dioctyl phthalate), DBP (dibutyl phthalate), and polyhydric alcohol from being attached to a wafer. Therefore, a chemical filter for absorbing and removing such material (hereinafter, chemical pollutants) is required to be installed in the CVD apparatus.

However, since the chemical filter removes the chemical pollutants by physical absorption and chemical reaction of an activated fiber impregnated with a chemical adhesive (hereinafter, activated fiber), the activated fiber being included in the chemical filter, the ability of the physical absorption and the chemical reaction undergoes time degradation. Thus, even if the CVD apparatus includes the chemical filter, an amount of the chemical pollutants and a density thereof in atmosphere of the housing should be estimated periodically or non-periodically. In addition, the cause of influx of the chemical pollutants into the housing is not confined to the time degradation of the chemical filter. In other words, an influx through a spacing of the housing, an influx through a cassette loading/unloading opening, and the like, can be the cause.

Among methods for estimating the amount and the density of the chemical pollutants in the housing, a method, that includes a step of absorbing the chemical pollutants in the atmosphere of the housing by an absorbent (e.g., active carbon and wafer) installed in the housing, a step of sampling the absorbed chemical pollutants, and a step of estimating the sampled chemical pollutants by an exclusive analyzer in off-line to announce a degree of contamination, is generally used. However, the method has following problems. First, an exclusive estimation system should be constructed. Second, an installation of the absorbent required for sampling the chemical pollutants affects an operation of the CVD apparatus. Third, it takes long time to acquire the estimation result in case an interval of a sampling time is long.

### SUMMARY OF THE INVENTION

It is, therefore, an object of the present invention to provide a substrate processing apparatus, which can automatically estimate a degree of contamination caused by chemical pollutants.

In accordance with one aspect of the invention, there is provided a substrate processing apparatus including: a housing including a process tube in which a substrate is processed; a microbalance, which is installed inside or outside of the housing, for detecting an amount of organic matters in atmosphere of the inside or the outside of the housing; and a heater for heating the microbalance to thereby eliminate materials absorbed on the microbalance.

In accordance with another aspect of the invention, there is provided a substrate processing apparatus including: a housing including a process tube in which a substrate is processed; a microbalance, which is installed inside or outside of the housing, for detecting an amount of organic matters in atmosphere of the inside or of the outside of the housing; and a thermo-hygrometer for measuring temperature and humidity in the atmosphere of the inside or outside of the housing.

In accordance with still another aspect of the invention, there is provided a substrate processing apparatus including: a housing including a process tube in which a substrate is processed; a microbalance, which is installed inside or outside of the housing, for detecting an amount of organic matters in atmosphere of the inside or the outside of the housing; and a dehumidifier for removing moisture in the atmosphere of the inside or the outside of the housing.

In accordance with still another aspect of the invention, there is provided a method for manufacturing a semiconductor device, including the steps of: detecting by using a microbalance an amount of organic matters in atmosphere of inside or outside of a housing, the housing including a process tube in which a substrate is processed; heating the microbalance to thereby eliminate materials absorbed on the microbalance; loading a substrate into the process tube; processing the substrate in the process tube; and unloading the substrate from the process tube.

### BRIEF DESCRIPTION OF THE DRAWINGS

The above and other objects and features of the present invention will become apparent from the following description of preferred embodiments given in conjunction with the accompanying drawings, in which:

FIG. 1 shows a side cut-away view of CVD (chemical vapor deposition) apparatus in accordance with a preferred embodiment of the present invention;

FIG. 2 describes a perspective view indicating a flow of a clean air in accordance with the preferred embodiment of the present invention;

FIG. 3 illustrates a block diagram of a chemical pollutants detecting unit included in the CVD apparatus in accordance with the preferred embodiment of the present invention;

FIG. 4 offers a block diagram of a chemical pollutants detecting unit in accordance with a second preferred embodiment of the present invention;

FIG. 5A shows a quartz crystal microbalance inserted into a sidewall of the housing while sampling the chemical pollutants and FIG. 5B provides a block diagram of a chemical pollutants detecting unit in accordance with a third preferred embodiment of the present invention; and

FIG. 6 presents a side cut-away view of a single wafer type CVD apparatus in accordance with another preferred embodiment of the present invention.

### DETAILED DESCRIPTION OF THE PREFERRED EMBODIMENTS

Hereinafter, preferred embodiments of the present invention are explained with reference to affixed drawings.

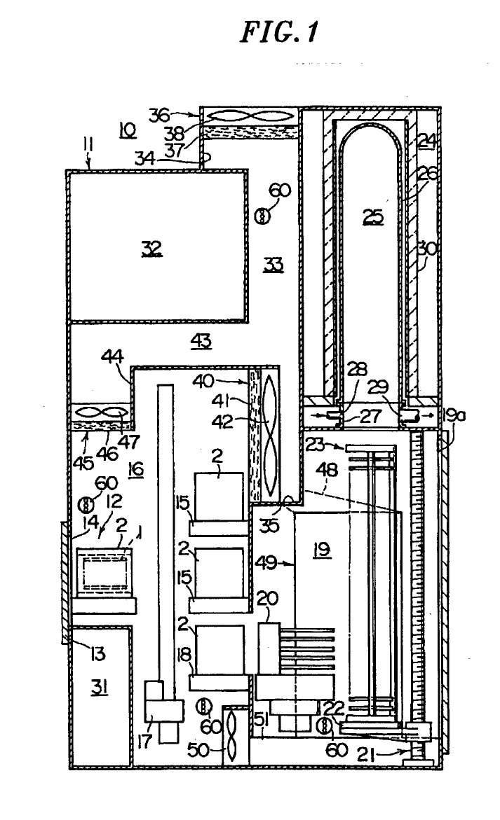

As shown in FIG. 1, a substrate processing apparatus (or a wafer processing apparatus) in accordance with the present invention includes a CVD apparatus 10 having a housing 11, which is an airtight chamber. In general, a kind of carrier (conveyance jig) for receiving and conveying wafers includes an open cassette (hereinafter, cassette), which has a box-shape form, approximately cube, with one pair of surfaces facing each other being opened, and a FOUP (front opening unified pod), which has a box-shape form, approximately cube, with one surface being opened, a cap being able to be attached to and detached from the one surface. In the CVD apparatus 10 in accordance with the present invention, a cassette 2 serves as a carrier of a wafer 1.

In a lower part of a front face of the housing 11, a cassette loading/unloading port (hereinafter, cassette port) 12 for loading/unloading the cassette 2 into/from the housing 11 is located. And on a front wall of the housing 11 facing the cassette port 12, a cassette loading/unloading opening 14 which is opened and closed by a front shutter 13 is located. The cassette 2 is loaded/unloaded through the cassette port 12 by a conveying unit (not shown) in process. At a rear of the cassette port 12 in the housing 11, a storage shelf 15, having a plurality of steps, for storing a plurality of cassettes 2 is constructed, with the plurality of steps being arranged in parallel. A cassette loading and transferring unit installing room 16, in which a cassette loading and transferring unit 17 having a SCARA (selective compliance assembly robot arm) is constructed, is located between the cassette port 12 and the storage shelf 15. The cassette loading and transferring unit 17 conveys the cassette 2 between the cassette port 12 and the storage shelf 15 and between the storage shelf 15 and a port for loading/unloading the wafer 1 (hereinafter, wafer port 18).

At a rear of the wafer port 18, a waiting room 19 in which a boat 23 stands by to be loaded/unloaded into/from a process tube 26 is located. And in front of the waiting room 19, a wafer loading and transferring unit 20, which conveys the wafer 1 between the wafer port 18 and the boat 23, is constructed. At a rear of the waiting room 19, a boat elevator 21, by which a sealed cap 22 supporting the boat 23 is lifted and lowered, is vertically constructed. That is, the sealed cap 22 is of a circular shape for sealing up the process tube 26 via a manifold 27, and the boat 23 rests on the basis of the sealed cap 22 vertically. The boat 23 is constructed such that the plurality of wafers 1 loaded thereon are arranged in parallel, with the center axis thereof being coincident, and are loaded/unloaded into/from a processing room 25 of the process tube 26 by moving up/down along with the movement of the sealed cap 22 which is lifted up/lowered down by the boat elevator 21.

At an upper part of a rear of the housing 11, a process tube installing room 24, in which the process tube 26 forming the processing room 25 rests on the basis of the waiting room 19 vertically via the manifold 27, is located. The manifold 27 is connected to a gas introducing pipe 28 for providing the processing room 25 with raw material gas, purge gas, and the like, and an exhaust pipe 29 for evacuating the processing room 25. A heater unit 30, supported by the housing 11, is located outside of the process tube 26, with the center axis thereof being coincident with that of the process tube 26. And the heater unit 30 is operated such that a fixed temperature distribution in the entire processing room 25 is maintained.

Moreover, at a lower part and an upper part of the cassette port 12 in the housing 11, a lower distributing board part 31 and an upper distributing board part 32, which are required for installing electric appliance, electric wiring, control appliance, and the like, are located respectively.

Between the upper distributing board part 32 and the process tube installing room 24, a duct 33 is installed in a vertical direction. An inhaling port 34 of the duct 33 is opened at an upper surface of the housing 11, and an exhaust nozzle 35 of the duct 33 is opened at a rear side of the storage shelf 15. A chemical filter unit 36 is installed in the inhaling port 34. The chemical filter unit 36 includes a chemical filter 37 and a plurality of fans 38, the chemical filter 37 being located in a downstream of the plurality of fans 38. In addition, the chemical filter 37 removes the chemical pollutants, e.g., acid gas, alkali gas, and organic gas, by physical absorption and chemical reaction of the activated fiber.

The exhaust nozzle 35 includes a clean unit 40 for the cassette loading and transferring unit installing room (hereinafter, first clean unit), which is arranged in a vertical direction to cover an entire surface of the exhaust nozzle 35. The first clean unit 40 includes a filter 41 for absorbing particles (hereinafter, particle filter) and a plurality of fans 42, the particle filter 41 being located in a downstream of the plurality of fans 42. A sub-duct 43 is diverged from a middle part of the duct 33, and an exhaust nozzle 44 of the sub-duct 43 is opened in a lower direction, right above the cassette port 12. The exhaust nozzle 44 includes a clean unit 45 for a cassette port (hereinafter, second clean unit), which is arranged in a parallel direction to cover an entire surface of the exhaust nozzle 44. The second clean unit 45 includes a particle filter 46 and a plurality of fans 47, the particle filter 46 being located in a downstream of the plurality of fans 47. A second sub-duct 48 is diverged from a lower terminal part of the duct 33, in a diagonal lower direction, and an exhaust nozzle of the second sub-duct 48 is connected to a clean unit 49 for the waiting room (hereinafter, third clean unit). The third clean unit 49 is constructed vertically such that a nearly entire surface of the waiting room 19 is covered. A detailed graphic representation is omitted, but the third clean unit 49 includes a particle filter and a plurality of fans, the particle filter being located in the downstream of the plurality of fans.

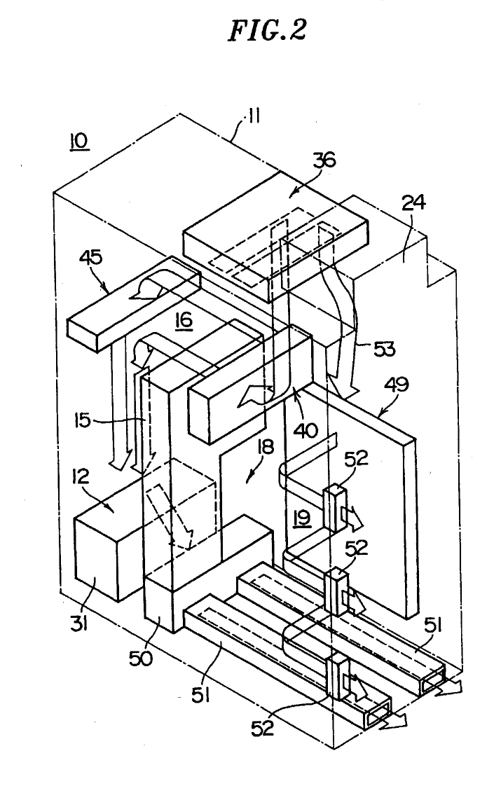

As shown in FIG. 2, a front exhaust fan 50 is constructed in parallel with the cassette port 12, to be extended in a right/left direction on a floor face of the cassette loading and transferring unit installing room 16, and a pair of exhaust ducts 51 are located on either side of a floor face of the waiting room 19 in parallel, the pair being vertical to the front exhaust fan 50. An exhaust nozzle of the front exhaust fan 50 is connected to inhaling ports of the pair of exhaust ducts 51, and an exhaust nozzle of the pair of exhaust ducts 51 is opened to exterior of the housing 11. At an opposite corner of the third clean unit 49, which is located at a rear part of the waiting room 19, three pieces of rear exhaust fans 52 are arranged in a regular row on a vertical line, and the rear exhaust fans 52 are constructed such that they inhale an atmosphere of the waiting room 19, which is then spouted to exterior of the waiting room 19.

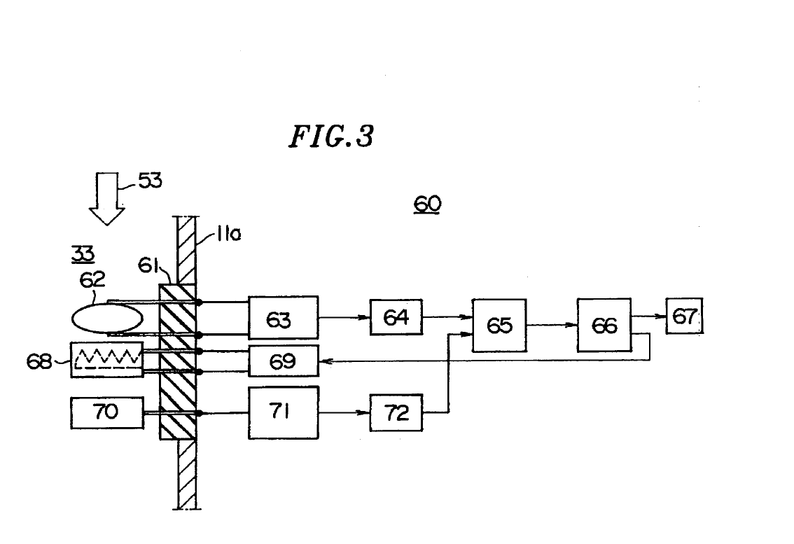

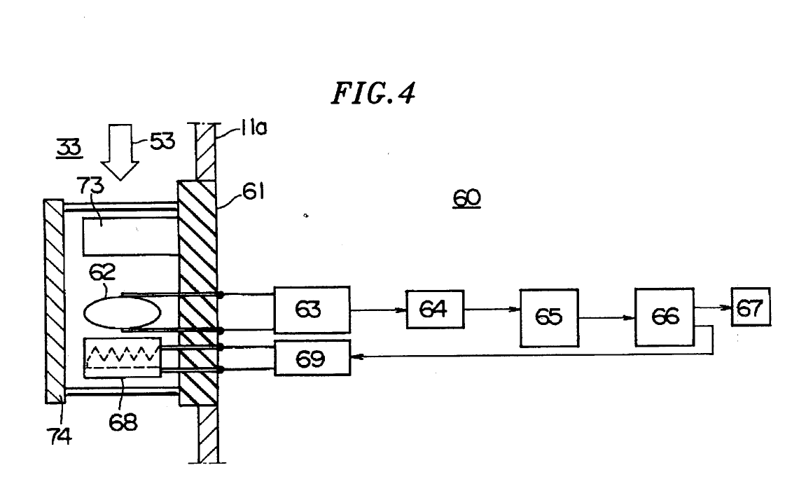

As shown in FIG. 1, a chemical pollutants detecting unit 60 (shown in FIG. 3) is installed at each of a middle part of the duct 33, the exhaust nozzle of the second clean unit 45, a lower part of the cassette loading and transferring unit installing room 16, and a lower part of the waiting room 19. As shown in FIG. 3, the chemical pollutants detecting unit 60 includes a supporting shaft 61 made out of insulating materials like ceramic and the like, and the supporting shaft 61 is inserted into a sidewall 11a of the housing 11 from outside of the housing 11. Inside of the housing 11, a quartz crystal microbalance (QCM) 62, which detects an increase of organic materials in the atmosphere of the duct 33 and the like, is supported by the supporting shaft 61. And terminals of the QCM 62 are withdrawn to an exterior of the housing 11 by penetrating the supporting shaft 61. An output port of an oscillation circuit 63, whose input port is connected to the terminals of the QCM 62, is connected to an input port of an oscillation frequency detecting block 64, whose output port is connected to a chemical pollutants calculating block (hereinafter, calculating block) 65. An output of the calculating block 65 is fed to a controller 66, and an output of the controller 66 is fed to an output unit 67 such as buzzer, lamp, printer, and the like, and a heater driving circuit 69.

Below the QCM 62, a heater 68 is installed to heat the QCM 62, and terminals of the heater 68 are withdrawn to exterior of the housing 11 by penetrating the supporting shaft 61. The heater driving circuit 69, connected to the terminals of the heater 68, receives the output of the controller 66. Moreover, below the heater 68, a thermo-hygrometer 70 is installed, a terminal thereof being withdrawn to exterior of the housing 11 by penetrating the supporting shaft 61. An output of a thermo-hygrometer driving circuit 71, connected to the terminal of the thermo-hygrometer 70, is connected to an input port of a temperature-humidity detecting block 72, whose output port is connected to the input port of the calculating block 65.

The operation of the CVD apparatus having above-mentioned structure is explained below.

As shown in FIG. 1, the cassette 2, which is provided to the cassette port 12 via the cassette loading/unloading opening 14, is conveyed to the storage shelf 15 by the cassette loading and transferring unit 17 in the cassette loading and transferring unit installing room 16, and then stored in the storage shelf 15 temporarily. And then, the cassette 2 is picked up and then conveyed to the wafer port 18 by the cassette loading and transferring unit 17. The plurality of wafers 1, which is received by the cassette 2 on the wafer port 18, is conveyed to a boat 23 by a wafer loading and transferring unit 20 and then charged at the boat 23.

And then the boat 23 is loaded into the processing room 25 surrounded by the process tube 26 by elevation of the boat elevator 21. When the boat 23 reaches an upper limit, a periphery of the upper face of the sealed cap 22 blocks the process tube 26 so that the processing room 25 is closed with airtight condition.

And then, a plurality of gases in the processing room 25 are exhausted by an exhaust pipe 29 to make the processing room 25 be kept at a fixed vacuum level, and the processing room 25 is heated by the heater unit 30 until a temperature therein reaches a fixed value. And then, a fixed amount of the raw material gases are provided to the processing room 25 through the gas introducing pipe 28, thereby forming some CVD layers on the wafer 1.

After a predetermined time required for processing the plurality of wafers 1 in the processing room 25 passes, the boat 23 is lowered by the boat elevator 21 until arriving at an original waiting location in the waiting room 19 (i.e., boat unloading).

After being processed, the wafer 1 on the boat 23 is unloaded to the waiting room 19, and then picked up by the wafer loading and transferring unit 20 to be conveyed to the wafer port 18, so that the wafer 1 is moved into the cassette 2, emptied, which was already conveyed to the wafer port 18. The cassette 2, which receives the wafer 1 which has been processed, is conveyed to a designated shelf among the storage shelves 15 by the cassette loading and transferring unit 17, and then stored on the designated shelf temporarily. And then the cassette 2 is conveyed to the cassette port 12 from the designated shelf by the cassette loading and transferring unit 17. And then the cassette 2 is conveyed to a next process.

Next, another wafers 1 are processed by the CVD apparatus 10 by repeating the above-mentioned operation.

As indicated by arrows in FIG. 2, while the above-mentioned operation is processed, a clean air 53 is spurted from the first clean unit 40, the second clean unit 45, the third clean unit 49 to the cassette loading and transferring unit installing room 16, the cassette port 12, the waiting room 19, respectively, and inhaled by the front exhaust fan 50 and the rear exhaust fan 52, and exhausted to exterior of the housing 11 through the exhaust duct S1. By this stream of the clean air 53, particles attached to the surface of the cassette 2 and the wafer 1 as well as particles generated due to driving of the cassette loading and transferring unit 17, the wafer loading and transferring unit 20 and the boat elevator 21 are dropped.

Herein, the inhaling port 34 of the duct 33 includes the chemical filter unit 36, so that the clean air 53 is spouted from the first clean unit 40, the second clean unit 45 and the third clean unit 49, with the chemical pollutants such as acid gas, alkali gas, organic gas, and the like, having already been removed therefrom.

However, since the chemical filter 37 removes the chemical pollutants by physical absorption and chemical reaction of the activated fiber, the ability of physical absorption and chemical reaction thereof undergoes the time degradation. Due to the time degradation, the chemical filter cannot get rid of the chemical pollutants completely so that the wafer 1 can be contaminated by the chemical pollutants, to thereby degrade the efficiency of the IC manufacturing method.

Therefore, in the preferred embodiment of the present invention, the chemical filter 37 is examined automatically whether or not the ability of removing the chemical pollutants thereby is degraded by the chemical pollutants detecting unit 60 installed in a downstream of the chemical filter unit 36. If the ability is found to have been degraded, the efficiency in the IC manufacturing method is prevented from being degraded by issuing an alarming signal.

Hereinafter, the operation and effect of the chemical pollutants detecting unit 60 are explained.

A varying amount of an oscillation frequency of the QCM 62 is represented by the following formula 1.

−Δf=Δm=(f²/N×A×ρ) [Formula 1]

In Formula 1, f represents a fundamental oscillation frequency, Δf shows the varying amount of the oscillation frequency, Δm offers a varying amount of the mass of the QCM, N describes the oscillation frequency integer, A illustrates the surface area of the QCM, and ρ provides a density of the quartz.

Herein, Δm is varied in case the moisture or the chemical pollutants in the atmosphere are attached to the surface of the QCM, so that a varying amount of the chemical pollutants can be acquired by calculating the humidity, the temperature, and Δm.

If the chemical pollutants are spouted from the chemical filter unit 36, the chemical pollutants are attached to the QCM 62 included in the chemical pollutants detecting unit 60, which is installed in the downstream of the chemical filter unit 36, thereby decreasing the fundamental oscillation frequency f. That is, considering the constant sampling time of the chemical pollutants detecting unit 60, as the density of the chemical pollutants becomes higher, an adhesive rate of the chemical pollutants becomes higher, so that Δf is small in case the density of the chemical pollutants is low, and Δf is large in case the density of the chemical pollutants is high. Therefore, the density of the chemical pollutants can be obtained by calculating Δf and using the Formula 1 and a Formula 2.

(An amount of chemical pollutants in the surface of the QCM)=b×(the density of chemical pollutants in the atmosphere)×{1−exp(−axt)} [Formula 2]

In the Formula 2, ‘a’ and ‘b’ are coefficients, and ‘t’ represents time. A reference value for the varying amount of the oscillation frequency Δf is set up at the controller 66 included in the chemical pollutants detecting unit 60, and in case Δf, which is calculated at the calculating block 65, is larger than the reference value, the controller 66 transfers an alarming signal to the output unit 67. Moreover, the chemical pollutants detecting unit 60 can be constructed such that the alarming signal is transferred to the output unit 67 in accordance with the density level of the pollutants in the atmosphere, e.g., high, middle, and low.

However, if the chemical pollutants attached to the QCM 62 remain attached thereto even after the sampling of the chemical pollutants is over, the fundamental oscillation frequency f is varied so that the accuracy of detecting the chemical pollutants by the QCM 62 is degraded. Therefore, considering the chemical pollutants detecting unit 60 in the preferred embodiment of the present invention, the chemical pollutants attached to the QCM 62 can be separated therefrom to thereby make the QCM 62 clean one by heating the QCM 62 through the heater 68, so that an original value of the fundamental oscillation frequency f can be recovered. Therefore, the accuracy of detecting the chemical pollutants by the QCM 62 is prevented from being degraded, and the repetitive detection of the chemical pollutants thereby becomes possible. A purifying heating temperature that makes the QCM 62 clean one can be optional only if it is above 250° C. but below a heat-resistant temperature of the QCM 62.

Moreover, before the above-mentioned chemical pollutants are detected, the QCM 62 can be heated until another optional temperature, a suitable range thereof being above the room temperature but below 100° C., i.e., below the purifying heating temperature, is reached so that the moisture attached to the surface of the QCM 62 is removed therefrom. Therefore, the accuracy of detecting the chemical pollutants by the chemical pollutants detecting unit 60 can be enhanced.

Furthermore, in case the QCM 62 is heated until still another optional temperature, a suitable range thereof being above the room temperature but below 250° C., is reached, organic matters with high-boiling point such as DBP and DOP remain, which can greatly affect the efficiency of the IC manufacturing method, but organic matters with low-boiling point is eliminated beforehand, which cannot greatly affect the efficiency of the IC manufacturing method, so that only organic matters with high-boiling point can be detected.

Moreover, a temperature and a humidity of the clean air 53 flowing in the duct 33 are measured by the thermo-hygrometer 70, and the measured temperature and humidity are fed to the calculating block 65, thereby compensating a result of the calculating block 65.

As mentioned above, the-chemical filter 37 is examined automatically whether or not an ability of removing the chemical pollutants thereby is degraded, with the help of the chemical pollutants detecting unit 60 installed in the duct 33.

However, the cause of an influx 6f the chemical pollutants into the housing 11 is not confined to the time degradation of the chemical filter 37, i.e., an influx through a spacing and a joint of wall surrounding the housing 11, an influx through the cassette loading/unloading opening 14 for the cassette port 12, an influx through a maintenance repair opening 19a in the waiting room, and the like, can be the cause. Therefore, the varying amount of the chemical pollutants in the cassette port 12, the cassette loading and transferring unit installing room 16, and the waiting room 19, should be preferably examined automatically.

Thus, in the CVD apparatus 10 in accordance with the preferred embodiment of the present invention, the chemical pollutants detecting units 60 are installed in a lower part of the exhaust nozzle of the second clean unit 45, the cassette loading and transferring unit installing room 16 and the waiting room 19, respectively, thereby preventing the wafer 1 from being contaminated, resulting in maintaining the efficiency of the IC manufacturing method. The operation of the respective chemical pollutants detecting units 60 in the cassette port 12, the cassette loading and transferring unit installing room 16, and the waiting room 19 are same as that in the duct 33, so that the detailed explanation thereof is omitted.

FIG. 4 is a block diagram representing a chemical pollutants detecting unit in accordance with the second preferred embodiment of the present invention.

Differences between the second preferred embodiment of the present invention and the first preferred embodiment of the present invention are that a dehumidifier 73, instead of the thermo-hygrometer, is installed in an upstream of the QCM 62 and an atmosphere separating wall 74 is supported by the supporting shaft 61.

In accordance with the second preferred embodiment of the present invention, since the effect of the humidity in the clean air 53 on the QCM 62 can be reduced by the dehumidifier 73, the accuracy of detecting the chemical pollutants 60 can be further enhanced.

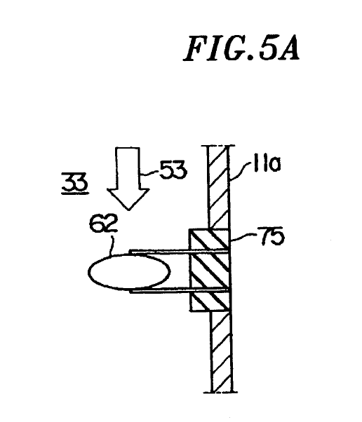

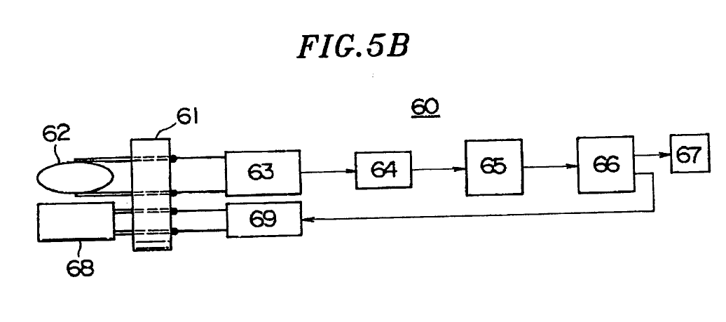

FIG. 5A shows a QCM 62 inserted into a sidewall of the housing 11a while sampling the chemical pollutants and FIG. 5B is a block diagram of a chemical pollutants detecting unit 60 in accordance with a third preferred embodiment of the present invention.

Differences between the third preferred embodiment of the present invention and the first or second preferred embodiment of the present invention are that the chemical pollutants detecting unit 60 is installed outside (off-line) of the housing 11 and the QCM 62 can be attached to and detached from the supporting shaft 61.

In accordance with the third preferred embodiment of the present invention, in case of sampling the chemical pollutants, the QCM 62 is separated from the supporting shaft 61 and then, as shown in FIG. 5A, inserted into a sidewall of the housing 11 while being loaded by a supporting shaft for sampling 75, thereby being installed at the middle of the duct 33. In general, the humidity and the temperature of the clean air 53 flowing in the duct 33 are strictly managed so that the omission of thermo-hygrometer does not have a side effect on the sampling of the chemical pollutants. After a predetermined sampling time has passed, the QCM 62, the chemical pollutants being attached thereto, is unloaded from the duct 33 and then, as shown in FIG. 5B, loaded to the supporting shaft 61 of the chemical pollutants detecting unit 60, so that the chemical pollutants begin to be inspected as mentioned above.

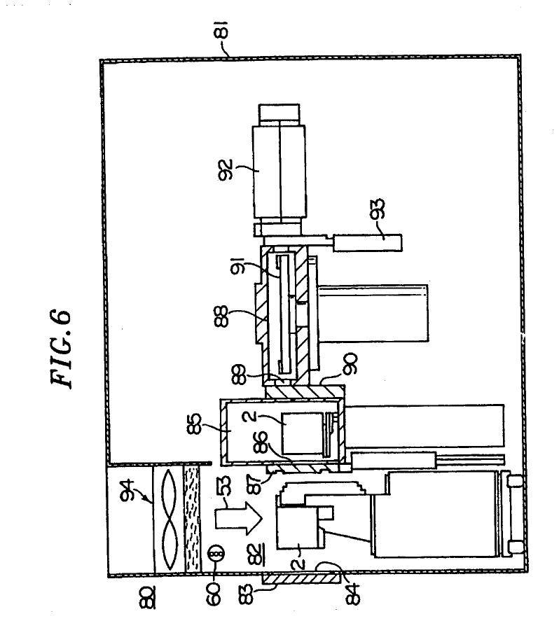

FIG. 6 presents a side cut-away view of a single wafer type CVD apparatus in accordance with another preferred embodiment of the present invention.

The single wafer type CVD apparatus 80 shown in FIG. 6 includes a housing 81. And at a lower part in a front face of the housing 81, a cassette port 82 for loading/unloading a cassette 2 into/from the housing 81 is installed. And at a front wall of the housing 81 facing the cassette port 82, a cassette loading/unloading opening 84 which is opened and closed by a front shutter 83 is located. The cassette port 82 loads/unloads the cassette 2 by a conveying apparatus (not shown) in process. A spare room 85, in which a cassette loading/unloading opening 86 being opened and closed by a gate valve 87 is installed, is constructed at a rear area of the cassette port 82 in the housing 81. A wafer loading and transferring unit installing room 88, in which a wafer loading/unloading opening 89 being opened and closed by a gate valve 90 is constructed, is located at a rear of the spare room 85. In the wafer loading and transferring unit installing room 88, a wafer loading and transferring unit 91 is constructed. At a rear of the wafer loading and transferring unit installing room 88, a process tube 92 is located. And a gate valve 93 is located between the process tube 92 and the wafer loading and transferring unit installing room 88.

In an upper part of the cassette port 82, a clean unit 94 is constructed in a lower direction, and the chemical pollutants detecting unit 60 is constructed around an exhaust nozzle of the clean unit 94. In accordance with another preferred embodiment of the present invention, a varying amount of the chemical pollutants at the cassette port 82 can be examined by the chemical pollutants detecting unit 60, so that the efficiency of the single wafer type CVD apparatus 80 is prevented from being degraded.

Moreover, the present invention is not confined to the above-mentioned embodiments, and various changes and modifications may be made without departing from the spirit and the scope of the invention.

For example, a surface acoustic wave (SAW) device can be preferably used instead of the QCM. Moreover, the chemical pollutants detecting unit can be installed outside of the housing, instead of inside thereof, so that a varying amount of the chemical pollutants in the exterior of the housing can be monitored.

The batch type vertical CVD apparatus and the single wafer type CVD apparatus are explained in the above-mentioned preferred embodiments of the present invention, but the present invention can be applied to the whole substrate processing apparatus such as a single wafer type plasma CVD apparatus and a sort of heat treatment apparatus (furnace), e.g., a batch type vertical diffusing apparatus, a single wafer type diffusing apparatus, an annealing apparatus, and the like.

Furthermore, the above-mentioned preferred embodiments of the present invention are not confined to the substrate processing apparatus, but include following methods using the substrate processing apparatus.

(1) A method for manufacturing semiconductor including a step of estimating a density and an amount of organic matters inside/outside of the substrate processing apparatus by using the QCM or the SAW and a step of eliminating the organic matters attached to the QCM or the SAW by heating it.

(2) A method for manufacturing semiconductor including a step of estimating a density and an amount of the organic matters inside/outside of the substrate processing apparatus by using the QCM or the SAW, and a step of heating the QCM and the SAW until an optional temperature, which is below the purifying heating temperature, is reached, before the step of estimating.

(3) A method for manufacturing semiconductor of (2), wherein, at the optional temperature, which is below the purifying heating temperature, moisture or specific organic matters can be removed from the surface of the QCM and the SAW.

(4) A method for estimating the density of chemical pollutants including a step of estimating a density and an amount of the organic matters inside/outside of the substrate processing apparatus by using the QCM or the SAW and a step of eliminating the organic matters attached to the QCM or the SAW by heating it.

(5) A method for estimating the density of chemical pollutants including a step of estimating a density and an amount of the organic matters inside/outside of the substrate processing apparatus by using the QCM or the SAW, and a step of heating the QCM and the SAW until an optional temperature, which is below the purifying heating temperature, is reached, before the step of estimating.

(6) A method for estimating the density of chemical pollutants of (5), wherein, at the optional temperature, which is below the purifying heating temperature, the moisture or specific organic matters can be removed from the surface of the QCM and the SAW.

While the invention has been shown and described with respect to the preferred embodiments, it will be understood by those skilled in the art that various changes and modifications may be made without departing from the spirit and the scope of the invention as defined in the following claims.

What is claimed is:

1. A substrate processing apparatus comprising:
a housing including a process tube in which at least one substrate is processed;
a microbalance, which is installed inside or outside of the housing, for detecting an amount of organic matters in atmosphere of the inside or the outside of the housing; and
a heater for heating the microbalance to thereby eliminate materials absorbed on the microbalance.

2. The substrate processing apparatus of claim 1, further comprising a controller for controlling a temperature, at which the materials absorbed on the microbalance are eliminated, to be a temperature at which organic matters absorbed on the microbalance are eliminated.

3. The substrate processing apparatus of claim 1, further comprising a controller for controlling a temperature, at which the materials absorbed on the microbalance are eliminated, to be above 250° C. but below a heat-resistant temperature of the microbalance.

4. The substrate processing apparatus of claim 1, further comprising a controller for controlling a temperature, at which the materials absorbed on the microbalance are eliminated, to be lower than a temperature at which organic matters absorbed on the microbalance are eliminated.

5. The substrate processing apparatus of claim 1, further comprising a controller for controlling a temperature, at which the materials absorbed on the microbalance are eliminated, to be a temperature at which moisture attached to the microbalance is eliminated.

6. The substrate processing apparatus of claim 1, further comprising a controller for controlling a temperature, at which the materials absorbed on the microbalance are eliminated, to be above the room temperature but below 100° C.

7. The substrate processing apparatus of claim 1, further comprising a controller for controlling a temperature, at which the materials absorbed on the microbalance are eliminated, to be a temperature at which organic matters absorbed on the microbalance are eliminated, boiling point of the organic matters being lower than that of DBP or DOP.

8. The substrate processing apparatus of claim 1, further comprising a controller for controlling a temperature, at which the materials absorbed on the microbalance are eliminated, to be above the room temperature but below 250° C.

9. The substrate processing apparatus of claim 1, wherein the microbalance is a quartz crystal microbalance or a surface acoustic wave device.

10. A substrate processing apparatus comprising:
a housing including a process tube in which at least one substrate is processed;
a microbalance, which is installed inside or outside of the housing, for detecting an amount of organic matters in atmosphere of the inside or of the outside of the housing; and
a thermo-hygrometer for measuring temperature and humidity in the atmosphere of the inside or outside of the housing.

11. A substrate processing apparatus comprising:
a housing including a process tube in which at least one substrate is processed;
a microbalance, which is installed inside or outside of the housing, for detecting an amount of organic matters in atmosphere of the inside or the outside of the housing; and
a dehumidifier for removing moisture in the atmosphere of the inside or the outside of the housing.

12. The substrate processing apparatus of claim 11, wherein the dehumidifier is located in an upstream of the microbalance.

13. A method for manufacturing a semiconductor device, comprising the steps of:
detecting by using a microbalance an amount of organic matters in atmosphere of inside or outside of a housing, the housing including a process tube in which a substrate is processed;
heating the microbalance to thereby eliminate materials absorbed on the microbalance;
loading at least one substrate into the process tube;
processing the substrate in the process tube; and
unloading the substrate from the process tube.

14. The method of claim 13, wherein a heating temperature, at which the step of heating is performed, is a temperature at which organic matters absorbed on the microbalance are eliminated.

15. The method of claim 13, wherein a heating temperature, at which the step of heating is performed, is above 250° C. but below a heat-resistant temperature of the microbalance.

16. The method of claim 13, wherein a heating temperature, at which the step of heating is performed, is lower than a temperature at which the organic matters absorbed on the microbalance are eliminated.

17. The method of claim 13, wherein a heating temperature, at which the step of heating is performed, is a temperature at which moisture attached to the microbalance is eliminated.

18. The method of claim 13, wherein a heating temperature, at which the step of heating is performed, is above the room temperature but below 100° C.

19. The method of claim 18, wherein the step of heating is executed before the step of detecting.

20. The method of claim 13, wherein a heating temperature, at which the step of heating is performed, is a temperature at which organic matters attached to the microbalance are eliminated, boiling point of the organic matters being lower than that of DBP or DOP.

21. The method of claim 13, wherein a heating temperature, at which the step of heating is performed, is above the room temperature but below 250° C.

22. The method of claim 13, wherein the microbalance is a quartz crystal microbalance or a surface acoustic wave device.
